(19) United States
(12) Patent Application Publication
(10) Pub. No.: US 2004/0021641 A1
(43) Pub. Date: Feb. 5, 2004

(54) Method for inputting a chinese character with phonetic symbols

(76) Inventor: Men-Jaw Ho, Nantou Hsien (TW)

Correspondence Address: Cooper & Dunham LLP, 1185 Avenue of the Americas, New York, NY, 10036, US

(21) Appl. No.: 10/208,470

(22) Filed: Jul. 30, 2002

(51) Int. Cl. H03K 17/94; H03M 11/00; G09G 5/00

(52) U.S. Cl. 345/171

(57) ABSTRACT

An inputting method for a Chinese character has acts of encoding a Chinese character into a consonant code and a vowel code, making an encoding phrase of the Chinese character and encoding an inputting code for the Chinese character. The encoding phrase is made of the Chinese character with a following Chinese character serving as a suffix according to habitual practice of the Chinese character. The inputting code is made of the consonant code of the Chinese character, the vowel code of the Chinese character and the vowel code of the suffix in the encoding phrase of the Chinese character. Accordingly, a Chinese character is rapidly inputted to a computer by means of striking the consonant code of the Chinese character, the vowel code of the Chinese character and the vowel code of the suffix in the encoding phrase of the Chinese character in sequence.

### BACKGROUND OF THE INVENTION

1. Field of the Invention

The present invention relates to a method for inputting a Chinese character, and more particularly to a method for inputting a Chinese character with phonetic symbols.

2. Description of Related Art

Many methods are used to input a Chinese character into a computer by a keyboard, like the phonetic symbol inputting method and so on. However, the conventional Chinese character input method has the drawbacks as follows:

1. The inputting speed of the conventional method is not rapid.

Because at least four or five strikes of keys are needed for inputting a Chinese character with the conventional inputting method, the inputting speed of the conventional method is not rapid.

2. To learn the conventional Chinese inputting method is difficult.

A special rule used to divide a Chinese character into several parts for inputting must be learned firstly before a user uses an inputting method to input Chinese characters into the computer. When a Chinese character is inputted, the user must divide the Chinese character into several parts according to the special rule and strikes the keys on the keyboard according to and corresponding to the divided parts. For a user, especially for a beginner, it is difficult to input Chinese with the conventional inputting method.

3. Mistakes occur easily while inputting Chinese characters with the conventional inputting method.

To input a Chinese character, actual sequential codes for input must be stroken on the keyboard and it is easy to make a mistake and incorrectly input a Chinese character with the conventional method due to a wrong strike on the keyboard or a wrong code taken apart by the special rule of the conventional method. Even when a Chinese character is inputted with the phonetic symbol inputting method, the user still can easily make a mistake because the user cannot clearly distinguish the consonants “ [symbol] ” due to any local accent or habitual practice when the user speaks Chinese.

In addition, all of the character and numeral keys on the keyboard are necessary for inputting with the conventional Chinese character inputting method. The area on the keyboard for inputting is broad, such that the inputting speed of conventional inputting method is low due to the broad inputting area. Furthermore, wrong key strike easily occurs in a large inputting area on the keyboard, and the conventional inputting method for the Chinese character is not efficient.

To overcome the shortcomings, the present invention tends to provide an inputting method for Chinese characters to mitigate or obviate the aforementioned problems.

### SUMMARY OF THE INVENTION

The main objective of the invention is to provide an inputting method for a Chinese character, having a rapid inputting speed and easily learned. The method has acts of encoding a Chinese character into a consonant code and a vowel code, making an encoding phrase of the Chinese character and encoding an inputting code for the Chinese character. The encoding phrase is made of the Chinese character with a following Chinese character serving as a suffix according to habitual practice of the Chinese character. The inputting code is made of the consonant code of the Chinese character, the vowel code of the Chinese character and the vowel code of the suffix in the encoding phrase of the Chinese character. Accordingly, a Chinese character is inputted to a computer by means of striking the consonant code of the Chinese character, the vowel code of the Chinese character and the vowel code of the suffix in the encoding phrase of the Chinese character in sequence.

Other objects, advantages and novel features of the invention will become more apparent from the following detailed description when taken in conjunction with the accompanying drawings.

### BRIEF DESCRIPTION OF THE DRAWINGS

FIG. 1 is a schematic drawing of a key arrangement of consonant codes and vowel codes of an inputting method for a Chinese character in accordance with the present invention;

FIG. 2 is a schematic drawing of a key arrangement of vowel codes of a suffix in an encoding phrase of the Chinese character of the inputting method in accordance with the present invention; and

FIG. 3 is a schematic drawing of a key arrangement of suffix of practice phrases of the inputted Chinese character in accordance with the present invention.

### DETAILED DESCRIPTION OF PREFERRED EMBODIMENT

A method for inputting a Chinese character into a computer in accordance with the present invention comprises acts as follows:

a. Encoding a Chinese character into a consonant code and a vowel code by the rule of phonetic symbols, wherein transition vowel, “ [symbol] ”, is combined with the consonant code. For example, “ [symbol] ” meaning “duck” in English is encoded into a consonant code “-” and a vowel code “ [symbol] ”.

b. Making an encoding phrase of the Chinese character with a following Chinese character serving as a suffix according to habitual practice of the Chinese character. For example, the encoding phrase of the Chinese character “ [symbol] ” can be “ [symbol] ” meaning “basis” in English, and the suffix is “ [symbol] ”. The encoding phrase of the Chinese character “ [symbol] ” can be “ [symbol] ” meaning “chicken (as food)” in English, and the suffix is “ [symbol] ”.

c. Encoding an inputting code for the Chinese character with the consonant code of the Chinese character, the vowel code of the Chinese character and the vowel code of the suffix in the encoding phrase of the Chinese character. For example, the inputting code of the Chinese character “ [symbol] ” is composed of “ [symbol] ” (the consonant code), “-” (the vowel code) and “ [symbol] ” (the vowel code of the encoding phrase). The inputting code of the Chinese character “ [symbol] ” is composed of “ [symbol] ” (the consonant code), “-” (the vowel code) and “ [symbol] ” (the vowel code of the encoding phrase). Consequently, each Chinese character can be encoded to a specific inputting code that is different from the inputting code of the other Chinese character even when two Chinese characters are homonymic.

Accordingly, a Chinese character can be inputted to a computer by means of striking the keys on the keyboard corresponding to the consonant code of the Chinese character, the vowel code of the Chinese character and the vowel code of the suffix in the encoding phrase of the Chinese character in sequence.

In such an inputting method, the quantity of codes for inputting a Chinese character is reduced to three, and the tone of the Chinese character does not need to be considered and to press the Space key on the keyboard is unnecessary so that the inputting speed is improved.

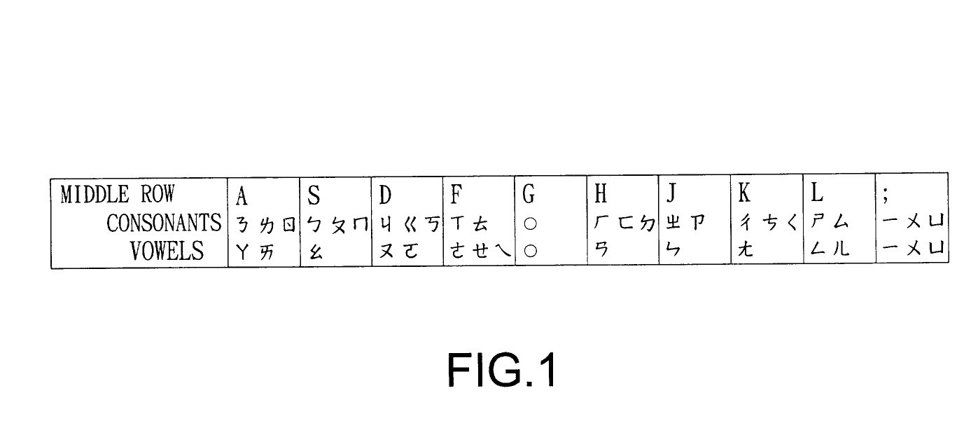

In practice, the keys corresponding to the consonants and the vowels of the phonetic symbols are both arranged on the middle row of the keyboard, i.e. “A, S, D, . . . , L” row, as shown in FIG. 1. Wherein, each key has at least one consonant or vowel corresponding to the key, and the symbol “◯” means no consonant or no vowel. When the user strikes one key on the middle row of the keyboard the first time, a corresponding consonant is inputted. When user strikes the keys on the middle row of the keyboard in the second time, a corresponding vowel is inputted. This means that when a same key is pressed twice, each strike to the key has a meaning different from that of the other so that the area of keys for inputting can be reduced to a small range. Therefore, the inputting speed with the method in accordance with the present invention is rapid.

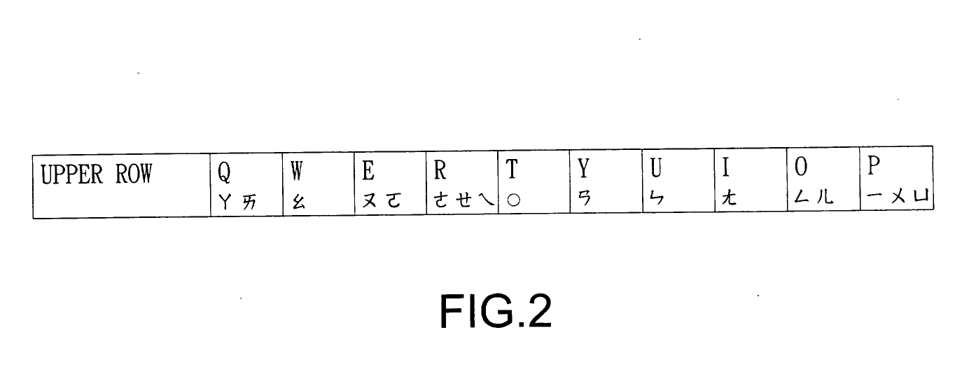

In addition, the keys corresponding to the vowels of the suffix of the encoding phrase are arranged on another row of the keyboard, such as the upper row, i.e. “Q, W, E, . . . , P” row, as shown in FIG. 2. With the inputting acts, about 3000 words in common use can be inputted so as to fit with 99% of the need of Chinese character input.

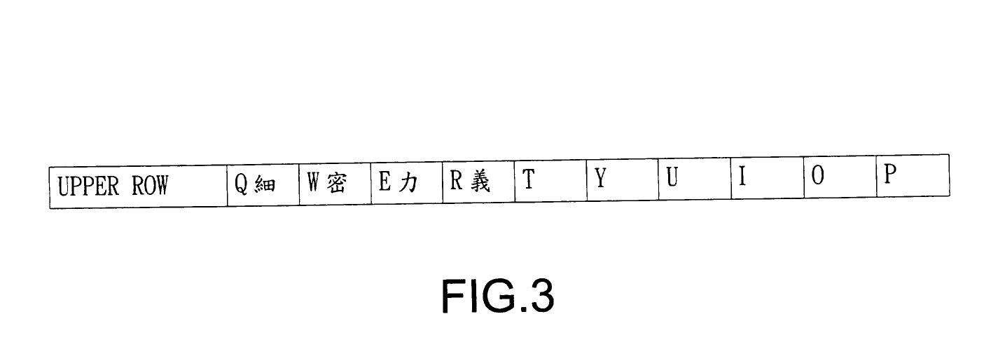

With reference to FIG. 3, after a Chinese character is inputted, keys on the upper row of the keyboard will be set to correspond to several suffixes of practice phrases made with the Chinese character as a prefix. For example, the keys “Q,W,E,R” on the upper row of the keyboard are set to correspond to the suffix “ [symbol] ” of the practice phrase “ [symbol] (meaning “fine”), [symbol] (meaning “precise”), [symbol] (meaning “energy”), [symbol] (meaning “cream”)” with a prefix “ [symbol] ”. When one of the keys on the list of suffixes is pressed, for example the “Q” key, the corresponding suffix, “ [symbol] ”, will be inputted.

From the above description, it is noted that the invention has the following advantages:

1. rapid inputting speed:

Because the quantity of inputting codes for inputting a Chinese character is reduced from at least five strikes including striking the space key on the keyboard to three strikes, the inputting speed for Chinese is rapid. In addition, with the input of the suffix as shown in FIG. 3, two Chinese characters can be inputted with four strikes, the inputting speed is further improved.

2. easy to learn:

Because the inputting method in accordance with the present invention is based on the rule of the phonetic symbols but does not involve dividing a character into several parts, to learn a difficult rule for dividing a character is unnecessary.

3. lower ratio of mistakes:

Several consonants or vowels with similar pronunciation can be arranged on a same key. Accordingly, mistakes will not easily occur, even when the user cannot clearly distinguish the consonants “ [symbol] ” due to his or her local accent or habitual practice. In addition, due to the small range of key arrangement, wrong key strike does not easily occur and thus the ratio of mistakes is further lowered.

Even though numerous characteristics and advantages of the present invention have been set forth in the foregoing description, together with details of the function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for inputting a Chinese character comprising acts as follows:
encoding a Chinese character into a consonant code and a vowel code by means of a rule of phonetic symbols, wherein a transition vowel is combined with the consonant code;
making an encoding phrase of the Chinese character with a following Chinese character serving as a suffix according to habitual practice of the Chinese character; and
encoding an inputting code for the Chinese character with the consonant code of the Chinese character, the vowel code of the Chinese character and the vowel code of the suffix in the encoding phrase of the Chinese character,
whereby the Chinese character can be inputted to a computer by means of striking keys on a keyboard corresponding to the consonant code of the Chinese character, the vowel code of the Chinese character and the vowel code of the suffix in the encoding phrase of the Chinese character in sequence.

2. The method for inputting a Chinese character as claimed in claim 1, wherein keys on a keyboard corresponding to the consonants and the vowels of the phonetic symbols are both arranged on a middle row of the keyboard.

3. The method for inputting a Chinese character as claimed in claim 2, wherein several consonants or vowels with similar pronunciation are arranged on a same key.
